(19) United States
(12) Patent Application Publication
(10) Pub. No.: US 2005/0096005 A1
(43) Pub. Date: May 5, 2005

(54) Wireless content player for a vehicle

(76) Inventors: David Vinson, Cupertino, CA (US); Yancy Chen, Campbell, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/698,886

(22) Filed: Oct. 31, 2003

(51) Int. Cl. H04B 1/06; H05K 11/00; H05K 11/02

(52) U.S. Cl. 455/345; 455/344

(57) ABSTRACT

A digital media player includes a mass storage device coupled to control circuitry. The player receives wired digital content from a home network, broadcast signals containing encoded broadcast content, and occupant inputs indicating broadcast digital content to be stored on the mass storage device. The control circuitry operates in a storage mode to receive wired digital content from the home network and store the received content on the mass storage device. In this mode, the control circuitry also operates in response to occupant inputs to store selected broadcast content on the mass storage device. The control circuitry further operates in a play mode to select content stored on the mass storage device in response to user inputs and to play the selected content. The broadcast signal may be, for example, a broadcast AM or FM signal.

### TECHNICAL FIELD

The present application relates generally to audio-video playing devices or players, and more specifically to audio-video players for vehicles.

### BACKGROUND OF THE INVENTION

For many years audio systems for vehicles such as cars have allowed occupants of the vehicle to listen to amplitude modulated (AM) and frequency modulated (FM) broadcasts. In recent years, such audio systems have become increasingly high performance and sophisticated, allowing occupants to listen to AM-FM broadcasts and to listen to audio content from cassette tapes and compact disks (CDs). Many current vehicle audio systems have superior sound quality and more comprehensive functionality than audio systems designed for homes not too many years ago.

A functional block diagram of a typical audio system 100 contained in a vehicle 102 is shown in FIG. 1, and includes a head unit 104 for allowing vehicle occupants to control various parameters of the system, such as the volume and source of audio content being played. The head unit 104 also typically includes a cassette tape player to allow an occupant to listen to cassette tapes when desired. A trunk unit 106 communicates with the head unit 104 either through wires interconnecting the two devices or through a wireless link 108 as depicted in FIG. 1. The trunk unit 106 contains various system components such as amplifiers (not shown), and also typically includes players for playing audio files stored on compact disks. In current audio systems 100, the trunk unit 106 typically includes a CD changer for playing audio files stored on a number of compact disks contained in the changer, and may include an MP3 player for playing audio files stored in MP3 format on compact disks. The trunk unit 106 applies audio signals to speakers 110 to play the audio content selected by an occupant via the head unit 104.

The conventional audio system 100 includes removable optical disks typically in the form of compact disks for storing audio content such as MP3 files or conventional compact disk audio files. Each disk can hold only a relatively small amount of data and in turn a relatively small number of audio files, limiting the audio content that an occupant may listen to without replacing disks in the trunk unit 106. While CD changers that can hold hundreds of disks are presently available, these changers are expensive and take up a relatively large amount of space in the trunk or other portion of the vehicle 102 containing the trunk unit 106. Moreover, even with a CD changer or MP3 player having a relatively large capacity for holding audio content, an occupant must still remember to insert the desired disks into the CD changer or MP3 player in order to have the content available. A danger of having all these compact disks in the vehicle 102 is that the disks can get lost, stolen, or damaged.

In the audio system 100, the head unit 104 communicates with the trunk unit 106 through the wireless link 108 as previously mentioned. In some audio systems 100, the trunk unit 106 communicates an FM signal that is received by the head unit 104. This is common where the CD changer in the trunk unit 106 is not factory installed but the head unit 104 is factory installed, and allows an occupant to add an aftermarket CD changer to his system 100 and thereby increase the number of compact disks that can be played at any given time. This approach sacrifices sound quality, however, since the quality an audio signal that may be generated from the FM signal including the encoded digital data from the CD is less than the quality of an audio signal that may be generated by directly using the digital data contained on the CD, as will be understood by those skilled in the art.

It should also be noted that current audio systems 100 play only audio files, as the name of the systems imply, and do not provide any functionality for processing any type of content other than audio content, such as video, photographic, or textual content. Moreover, current audio systems do not provide functionality for recording desired content and then playing that recorded content at a later time. In the present description, the terms “content” or “digital content” denote any type of information available on the Internet or other computer network, such as audio, video, graphics, text, and so on, and may alternately be referred to as a type of file (e.g., an audio content file or audio file) or merely as content (e.g., audio content or audio digital content) in the present description.

There is a need for a system and method of easily providing an occupant of a vehicle with large amounts of various types of content.

### SUMMARY OF THE INVENTION

According to one aspect of the present invention, a digital media player includes a mass storage device coupled to control circuitry. The player receives wired digital content from a home network, broadcast signals containing encoded broadcast content, and occupant inputs indicating broadcast digital content to be stored on the mass storage device. The control circuitry operates in a storage mode to receive wired digital content from the home network and store the received content on the mass storage device. In this mode, the control circuitry also operates in response to occupant inputs to store selected broadcast content on the mass storage device. The control circuitry further operates in a play mode to select content stored on the mass storage device in response to user inputs and to play the selected content. The broadcast signal may be, for example, a broadcast AM or FM signal.

### BRIEF DESCRIPTION OF THE DRAWINGS

FIG. 1 is a functional block diagram of a vehicle including a conventional vehicle audio system.

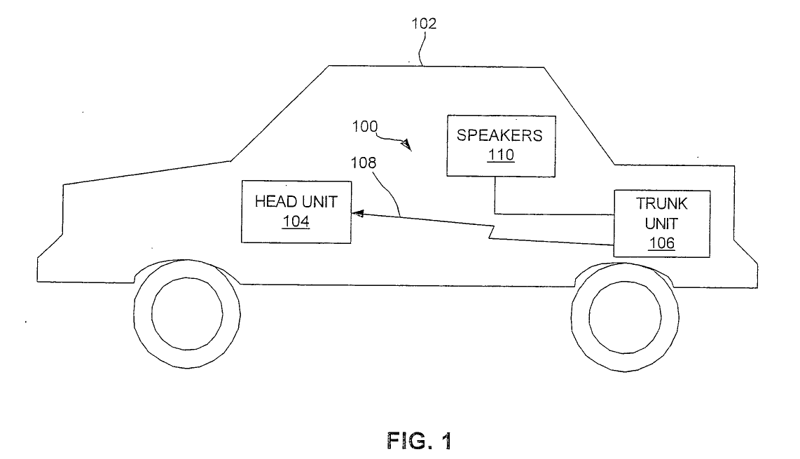

FIG. 2 is a functional block diagram of a digital content system including a digital media player contained in a vehicle and coupled through a wireless link to a home network according to one embodiment of the present invention.

FIG. 3 is a more detailed functional block diagram illustrating one embodiment of the digital media player of FIG. 2.

### DETAILED DESCRIPTION OF PREFERRED EMBODIMENTS

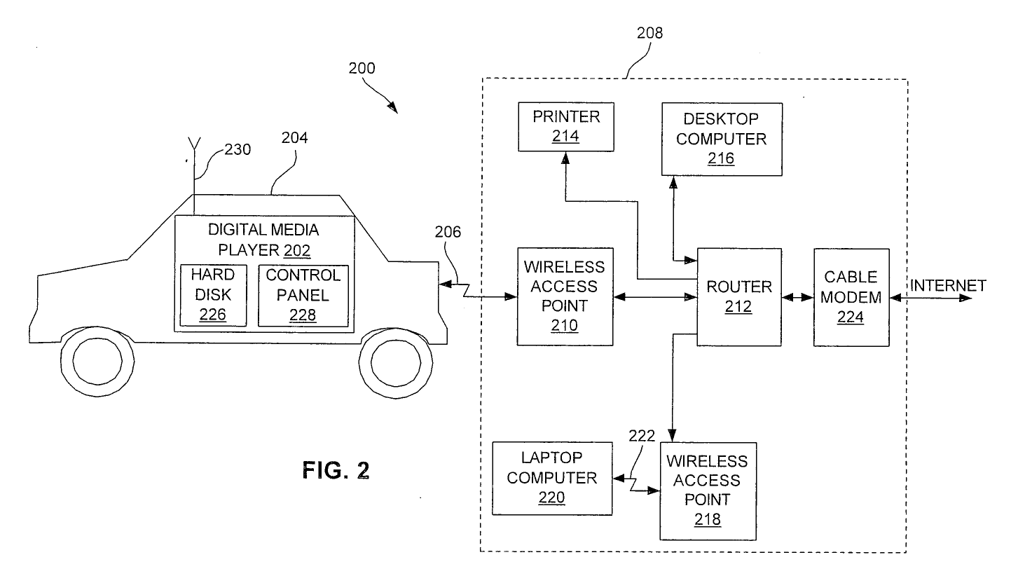

FIG. 2 is a functional block diagram of a digital content system 200 including a digital media player 202 contained in a vehicle 204 and coupled through a wireless link 206 to a home network 208 according to one embodiment of the present invention. In operation, various types of content in the form of audio, video, and navigational files, for example, are automatically transferred to the digital media player 202 when the player is proximate a wireless access point 210 contained in the home network 208, and the digital media player is also programmable to record desired AM or FM broadcasts for playback at a later time, as will be explained in more detail below.

In the following description, certain details are set forth in conjunction with the described embodiments of the present invention to provide a sufficient understanding of the invention. One skilled in the art will appreciate, however, that the invention may be practiced without these particular details. Furthermore, one skilled in the art will appreciate that the example embodiments described below do not limit the scope of the present invention, and will also understand that various modifications, equivalents, and combinations of the disclosed embodiments are within the scope of the present invention. Finally, the operation of well known components or conventional techniques have not been shown or described in detail below to avoid unnecessarily obscuring the present invention.

In the digital content system 200, the home network 208 further includes a router 212 coupled to the wireless access point 210, which functions as a communications hub coupling the digital media player 202 to the router through the communications link 206. The wireless access point 210 would typically be contained in a garage of a residence where the vehicle 204 is parked, or be positioned inside the residence adjacent a parking location of the vehicle. A printer 212 and desktop computer 216 are also coupled to the router 212, along with another wireless access point 218 that couples a laptop computer 220 to the router through a wireless link 222. The router 212 operates in a conventional manner to forward data packets from one device to another, where a device corresponds to any component coupled to the router. For example, the router 212 may forward data packets corresponding to a text file to be printed from the laptop computer 220 to the printer 214. More specifically, the laptop computer 220 transfers the data packets through the wireless link 222 and wireless access point 218 to the router 212 which, in turn, forwards the data packets to the printer 214 for printing. The router 212 also provides the desktop computer 216 and laptop computer 220 access to the Internet through a cable modem 224 coupled to the router in a conventional manner. In this way, either the desktop computer 216 or laptop computer 220 may access various types of content available on the Internet, such as audio, video, graphics, and text files.

The digital media player 202 includes a mass storage device such as a hard disk 226 for storing digital content transferred to the player from the home network 208. A control panel 228 in the digital media player 202 receives occupant inputs from an occupant of the vehicle 204, and provides the occupant with selected content stored on the hard disk 226 in response to the occupant inputs. The control panel 228 may include, for example, buttons, knobs, switches, and displays that allow an occupant to provide occupant inputs to select the desired content stored on the hard disk 226. The digital media player 202 also includes an antenna 230 for receiving a broadcast signal, such as an AM/FM broadcast signal. The occupant may program the player 202 via the control panel 228 to store on the hard disk 226 selected broadcast content encoded on a received broadcast signal. For example, the occupant could program the player 202 to store on the hard disk 226 the broadcast content corresponding to a favorite radio show of his that is broadcast during a work day. The occupant may then use the control panel 228 to access the broadcast content stored on the hard disk 228 and thereby replay the show on his way home from work that evening or at any later point in time.

In operation, an occupant would typically access digital content on the Internet or other computer network via the desktop computer 216, and then download selected “wired digital content” to be transferred to the digital media player 202 onto the desktop computer. In the present description, the term occupant is used to refer to a person using the digital media player 202 or desktop computer 216, while the term “wired digital content” is used to refer to content from the Internet or other computer network. Alternatively, wired digital content could be automatically transferred to the desktop computer 216 based upon profile information entered by the occupant, or content could be automatically selected and transferred to the desktop computer based upon prior content selections by the occupant. As previously mentioned, the selected wired digital content may be any type of content, such as MP3 audio files, video files, or bitmap files corresponding to navigational maps.

Once the selected wired digital content is stored on the desktop computer 216, the content is transferred through the router 212, wireless access point 210, and link 206 to the hard disk of the digital media player 202 when the player is proximate the wireless access point. The specific event triggering transfer of the content from the desktop computer 216 to the digital media player 202 may vary. For example, the transfer may be triggered simply by the digital media player 202 being proximate the wireless access point 210. Thus, whenever the vehicle 204 pulls into the garage or is otherwise proximate the wireless access point 210, the presence of the player 202 is detected, causing the desktop computer 216 transfer the appropriate digital content to the hard disk 226 in the digital media player 202.

In another embodiment, the event triggering transfer of the wired digital content from the desktop computer 216 to the digital media player 202 is the starting or turning off of the vehicle 204. The digital media player 202 is proximate the wireless access point 210 whenever the vehicle 204 pulls into the garage or is otherwise properly positioned. Thus, in one embodiment the wired digital content is transferred to the digital media player 202 whenever the vehicle turned off. In this way, whenever the occupant comes home and pulls the vehicle 204 into the garage, transfer of wired digital content to the digital media player 202 is initiated in response to the vehicle turning off to automatically update the wired digital content stored on hard disk 226 of the player. In another embodiment, the transfer of wired digital content from the desktop computer 216 to the player 202 is initiated in response to the vehicle 204 being started. In still another embodiment, the wired digital content is transferred to the digital media player 202 at predetermined times. For example, the vehicle 204 will presumably be parked in the garage at, for example, 3:00 AM, and thus at this time wired digital content is automatically transferred to the digital media player 202. In any of these embodiments, communication may occur between the player 202 and desktop computer 216 so that only new wired digital content is transferred to the player. For example, just prior to a transfer commencing, the player 202 may send a list of current content files to the computer 216 which, in turn, only sends new content files not contained on the list.

The digital content system 200 further operates to allow an occupant to store selected broadcast content received by the digital media player 202 via the antenna 230. The term “broadcast content” is used to refer to content encoded on a broadcast signal and stored directly onto the hard disk 226 of the digital media player 202. In operation, the occupant uses the control panel 228 to select desired broadcast content to be stored onto the hard disk 226, typically selecting a station and time at which to start recording such content and a time at which to end recording such content. For example, a favorite show of the occupant may be broadcast by radio station WNPR at 94.9 Mhz on the FM band from 12:00-1:00 PM each weekday. The occupant would then program the station and the start and end times into the digital media player 202, and the player would then store on the hard disk 226 the an audio file corresponding to this broadcast content. The occupant could then, for example, select this file on his way home from work and listen to his favorite show. Information regarding upcoming programs could also be encoded on the broadcast signal to allow an occupant to select desired broadcast content merely by identifying a desired show. This operational mode of the system 200 may be termed a “personal audio recording” (PAR) function, which is analogous to a “personal video recording” (PVR) function provided by services such as TiVo. Moreover, although a radio station is used as an example of a broadcast content, the broadcast content could be audio and video content broadcast by a television station, or could be any other type of content broadcast over a relatively large geographic area via a wireless network.

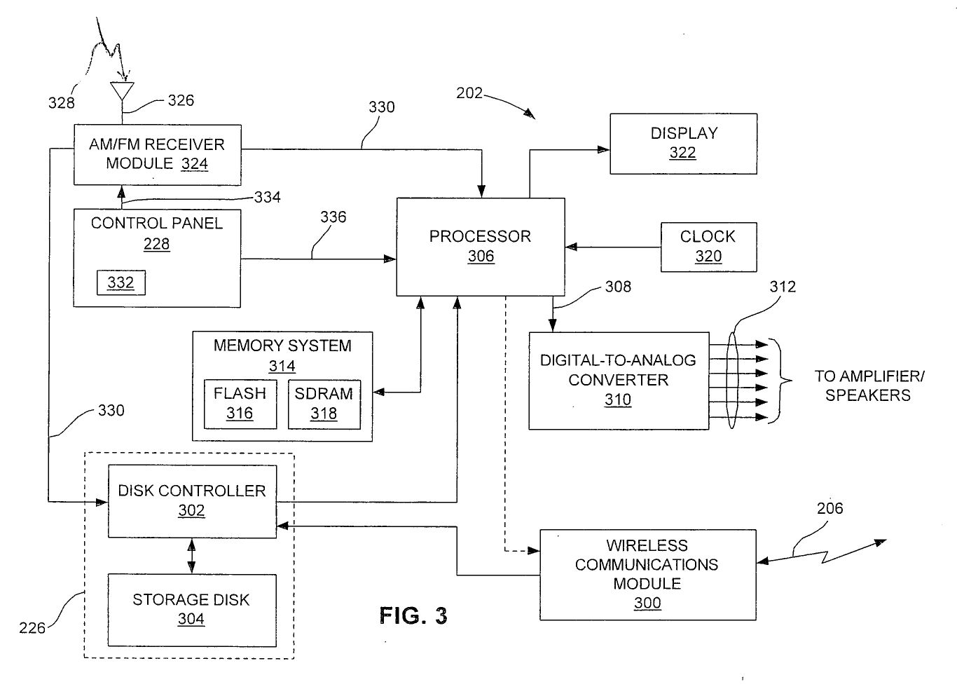

FIG. 3 is a more detailed functional block diagram illustrating one embodiment of the digital media player 202 of FIG. 2. The digital media player 202 includes a wireless communications module 300 receives data on the wireless communications link 206 and provides the data to the hard disk 226. More specifically, the hard disk 226 includes a disk controller 302 that controls the transfer of data to and from a storage disk 304 which stores data, where the storage disk is typically a magnetic disk but may be any suitable mass storage media. The disk controller 302 transfers data received from the wireless communications module 300 to the hard disk for storage. A processor 306 receives content stored on the storage disk 304 via the disk controller 302, and processes the content to generate digital signals 308 corresponding to the stored content. For example, where the content is audio files stored in MP3 format, the processor 306 decodes the MP3 files to generate corresponding digital signals 308. A digital-to-analog converter 310 generates a number of analog audio signals 312 in response to the digital signals 308, and these analog signals 312 are applied to an amplifier or speakers (not shown) to generate audible sounds.

A memory system 314 is coupled to the processor 306 and includes boot and operating system information contained in FLASH memory 316 and includes synchronous dynamic memory (SDRAM) 318 for storing data and programs being executed by the processor. A real-time clock 320 generates a time that is applied to the processor 306, and is used by the processor, for example, in determining when to record broadcast content received by the digital media player 202, as previously discussed. The digital media player 322 may also include a display 322 that the processor 306 drives to display video, photographic, text, or other types of visual content stored on the storage disk 304. An AM/FM receiver module 324 is coupled to an antenna 326 to receive broadcast signals 328, which in this case correspond to AM/FM broadcast signals. The AM/FM broadcast signals 328 are analog signals, and the receiver module 324 demodulates and decodes these analog signals to generate corresponding digital signals 330, as will be appreciated by those skilled in the art. When an occupant is listening to a radio station, the digital signals 330 are applied to the processor 306 which, in turn, processes these signals to generate the digital signals 308 and the converter 310 generating the audio signals 312 responsive to the digital signals 308. When the player 202 is programmed to record broadcast content contained on the broadcast signal 328, the receiver module 324 provides the corresponding digital signals 330 the disk controller 302 which, in turn, provides the signals to the storage disk 304 for storage.

The control panel 228 is coupled to the receiver module 324 to program the module to record desired broadcast content in response to occupant input applied to control inputs 332, which may include buttons, switches, and knobs. In response to the control inputs 332, the control panel 228 applies corresponding electrical signals 334 to the receiver module 324 to control operation of this module, such as to select the radio station to be listened to and to select the AM or FM band. The control panel 228 also generates electrical signals 336 in response to control inputs 332 and applies these signals to the processor 306 to control the selection of content to be played by the digital media player 202.

In operation, the digital media player operates in either a storage mode or a play mode. In the storage mode, wired digital content is received by the wireless communications module 300 via the link 206 and stored on the storage disk 304 via the disk controller 302. Similarly, an occupant applies control inputs 332 to the control panel 228 to select desired broadcast content to be stored on the storage disk 304, and the receiver module 324 applies the digital signals 330 corresponding to the desired broadcast content to the disk controller 302. The disk controller 302 applies the digital signals 330 to the storage disk 304 for storage to thereby store the selected broadcast content on the storage disk.

In the play mode, an occupant applies control inputs 332 to the control panel 228 to select the desired content to be played by the player. In response to the control inputs 332, the control panel generates signals 336 causing the processor 306 to accesses the selected content files stored on the storage disk 304 and to thereafter process these selected content files to play the selected content. For example, where the selected content files are audio files the processor 306 decodes the files to apply signals 308 to the converter 310 which, in turn, applies corresponding analog signals 312 to speakers (not shown). Where the selected content are video files, the processor 306 decodes the files to apply signals 308 to the converter 310 to generate corresponding audio signals 312 and drives the display 322 to generate the corresponding video images. In the play mode, the occupant may also select to listen to a real time radio broadcast, in which case the occupant provides the appropriate control inputs 332 and the control panel 228 applies the corresponding signals 334 to the receiver module 324. The receiver module 324 applies the digital signals 330 corresponding to the selected station to the processor 306, which processes these signals and provides corresponding signals 308 to the converter 310.

In the described example embodiments of the present invention, one skilled in the art will understand suitable circuitry for forming the various components described. For example, in the embodiment of the digital media player 202 shown in FIG. 3, suitable circuitry for forming the components 300-334 will be understood by those skilled in the art. The same is true of the home network 208 of FIG. 2, where each of the described components 210-224 is a commercially available component, and the circuitry and operation of such components is well understood by those skilled in the art.

Even though various embodiments of the present invention have been set forth in the foregoing description, the above disclosure is illustrative only, and changes may be made in detail and yet remain within the broad principles of the present invention. One skilled in the art will appreciate that the example embodiments described above do not limit the scope of the present invention, and will also understand various modifications, equivalents, and combinations of such embodiments are within the scope of the present invention. Therefore, the present invention is to be limited only by the appended claims.

1. A digital media player for a vehicle, comprising:
a mass storage device operable to store digital content and to provide the stored digital content; and
control circuitry coupled to the mass storage device, the control circuitry adapted to receive wired digital content from a home network and to receive broadcast signals containing encoded broadcast content, and being further adapted to receive occupant inputs indicating broadcast digital content to be stored on the mass storage device, the control circuitry operable in a storage mode to receive wired digital content from the home network and store the received content on the mass storage device and operable in response to occupant inputs to store selected broadcast content on the mass storage device, and the control circuitry operable in a play mode to select content stored on the mass storage device in response to user inputs and to play the selected content.

2. The digital media player of claim 1 wherein the control circuitry is further adapted to receive occupant inputs indicating desired wired digital content to be transferred to the mass storage device, and wherein the control circuitry is operable to communicate with the home network responsive to the occupant inputs to receive and store the desired wired digital content.

3. The digital media player of claim 1 wherein the mass storage device comprises a hard disk.

4. The digital media player of claim 1 wherein wired digital content comprises at least one of audio, video, photographic, and textual content.

5. The digital media player of claim 1 wherein the wired digital content includes navigational files which, when played, allow the occupant to navigate the vehicle to a desired location.

6. The digital media player of claim 1 wherein the broadcast signals comprise at least one of AM and FM broadcast signals.

7. The digital media player of claim 1 wherein the control circuitry operates in the storage mode to receive wired digital content from the home network responsive to the digital media player being proximate the home network.

8. The digital media player of claim 1 wherein the control circuitry operates in the storage mode to receive wired digital content from the home network at predetermined times when the digital media player is proximate the home network.

9. The digital media player of claim 1 wherein the control circuitry is further adapted to receive an activation signal, and wherein the control circuitry operates in the storage mode to receive wired digital content from the home network responsive to the activation signal being activated.

10. A digital media player, comprising:
a processor;
a mass storage device coupled to the processor;
a broadcast receiver module coupled to the processor and coupled to the mass storage device;
a control panel coupled to the broadcast receiver module; and
a wireless communications module coupled to the mass storage device.

11. The digital media player of claim 10 wherein the broadcast receiver module comprises an AM/FM receiver module.

12. The digital media player of claim 10 wherein the processor comprises a digital signal processor.

13. The digital media player of claim 10 wherein the mass storage device comprises a hard disk coupled to a disk controller.

14. The digital media player of claim 10 further comprising a display coupled to the processor.

15. The digital media player of claim 10 further comprising a digital-to-analog converter coupled to the processor.

16. The digital media player of claim 10 further comprising speakers operable to generate audible sounds responsive to signals provided by the processor.

17. A digital content system, comprising:
a home network adapted to receive and store content from a computer network, and including a wireless communications port to communicate with external devices; and
a digital media player contained in a vehicle, the digital media player including,
a mass storage device operable to store digital content and to provide the stored digital content; and
control circuitry operable to communicate with the home network through the wireless communications port, the control circuitry coupled to the mass storage device and being adapted to receive broadcast signals containing encoded broadcast content and to receive occupant inputs indicating broadcast digital content to be stored on the mass storage device, the control circuitry operable in a storage mode to receive wired digital content from the home network and store the received content on the mass storage device, and operable in response to occupant inputs to store selected broadcast content on the mass storage device, and the control circuitry operable in a play mode to select content stored on the mass storage device in response to user inputs and to play the selected content.

18. The digital content system of claim 17 wherein the control circuitry is further operable to receive an activation signal from the vehicle and in response to the activation signal being operable to initiate operation in the storage mode to receive wired digital content from the home network.

19. The digital content system of claim 18 wherein the vehicle activates the activation signal responsive to the vehicle being turned off.

20. The digital content system of claim 18 wherein the vehicle activates the activation signal responsive to the vehicle being turned on.

21. The digital content system of claim 17 wherein the control circuitry operates in the storage mode to receive wired digital content from the home network responsive to the vehicle being proximate the wireless communications port in the home network.

22. The digital content system of claim 17 wherein the control circuitry operates in the storage mode to receive wired digital content from the home network at predetermined times when the vehicle is proximate the wireless communications port in the home network.

23. The digital content system of claim 17 wherein the control circuitry is further adapted to receive occupant inputs indicating desired wired digital content to be transferred to the mass storage device, and wherein the control circuitry is operable to communicate with the home network responsive to the occupant inputs to receive and store the desired wired digital content.

24. The digital content system of claim 17 wherein wired digital content comprises at least one of audio, video, photographic, and textual content.

25. The digital content system of claim 17 wherein the wired digital content includes navigational files which, when played, allow an occupant to navigate the vehicle to a desired location.

24. The digital content system of claim 17 wherein the broadcast signals comprise at least one of AM and FM broadcast signals.

25. A method of playing digital content in a vehicle, comprising:
positioning the vehicle proximate a specific location;
when positioned in the specific location, storing wired digital content on a mass storage device contained in the vehicle;
receiving broadcast signals containing encoded broadcast content;
from within the vehicle, selecting broadcast content to be stored on the mass storage device;
storing the selected broadcast content;
selecting content stored on the mass storage device; and
playing the selected content.

26. The method of claim 25 wherein the broadcast signals comprise AM/FM broadcast signals.

27. The method of claim 25 wherein positioning the vehicle proximate a specific location comprising positioning the vehicle proximate a residence.

28. The method of claim 25 wherein storing wired digital content on a mass storage device contained in the vehicle comprises storing at least one of audio, video, photographic, and textual content.

29. The method of claim 25 wherein storing wired digital content on a mass storage device contained in the vehicle comprises storing navigational files which, when played, allow an occupant to navigate the vehicle to a desired location.

30. The method of claim 25 wherein playing the selected content comprises generating audible sounds where the selected content is audio content and generating visual displays where the selected content is video, photographic, navigational, or other types of visual content.
